(19) United States
(12) Patent Application Publication
(10) Pub. No.: US 2005/0255245 A1
(43) Pub. Date: Nov. 17, 2005

(54) Method and apparatus for the chemical vapor deposition of materials

(76) Inventors: Mark A. Fanton, Cabot, PA (US); David W. Snyder, Leechburg, PA (US); Marek Skowronski, Murrysville, PA (US)

Correspondence Address: GIFFORD, KRASS, GROH, SPRINKLE & CITKOWSKI, P.C, PO BOX 7021, TROY, MI, 48007-7021, US

(21) Appl. No.: 11/032,449

(22) Filed: Jan. 10, 2005

Related U.S. Application Data
(60) Provisional application No. 60/536,122, filed on Jan. 13, 2004.

(51) Int. Cl. C23C 16/00

(52) U.S. Cl. 427/255.28; 118/715

(57) ABSTRACT

The halide chemical vapor deposition process deposits a chemical compound comprised of at least two different elements. The method employs a first process gas which includes a halogenated compound of a first one of the at least two different elements, and a second process gas which includes hydrogen and a second one of at least two different elements. The process gases are maintained in separation until they are contacted in a deposition chamber proximate a substrate. The gases, which are generally preheated to a temperature of less than their thermal decomposition temperatures, are contacted in a deposition region proximate the substrate, and react to generate a deposition species and a hydrogen halide which is removed. Also disclosed is an apparatus for practicing the invention.

### REFERENCE TO RELATED APPLICATION

This patent application claims priority of U.S. provisional patent application Ser. No. 60/536,122, filed Jan. 12, 2004, and entitled “Method and Apparatus for the Chemical Vapor Deposition of Materials.”

### STATEMENT OF GOVERNMENT INTEREST

The invention was made with government support under contract number N002402D6604 awarded by the Air Force Research Laboratory, Materials Directorate. The government has certain rights in the invention.

### FIELD OF THE INVENTION

This invention relates generally to methods and apparatus for synthesizing high purity materials. More specifically, the invention relates to methods and apparatus for the synthesis of highly crystalline, high-purity materials such as wide band gap semiconductors, non-oxide ceramics and the like.

### BACKGROUND OF THE INVENTION

There is a growing need for single crystal or otherwise highly ordered specialty materials such as wide band gap semiconductors, non-oxide ceramics and the like. Such materials have significant utility as components of advanced electronic devices which are operable under extreme temperature conditions. Materials of this type generally have very high melting points, which fact makes them difficult to prepare in a highly ordered, high-purity form.

Single crystal silicon carbide is one such material, and the principles of the present invention will be explained with particular reference to the preparation of single crystal silicon carbide material. However, it is to be understood that the present invention may likewise be employed for the fabrication of other high-temperature materials including Group III nitrides as well as other wide band gap semiconductors and non-oxide ceramics.

A number of approaches have been implemented in the prior art for the preparation of single crystal silicon carbide and the like. In one approach, generally referred to as physical vapor transport (PVT), a body of silicon carbide is heated in a deposition chamber under reduced pressure. A substrate having a silicon carbide seed crystal supported thereupon is maintained in the deposition chamber, and sublimated vapor of the silicon carbide condenses on the seed crystal causing the growth of a body of crystalline silicon carbide. Problems occur with this method since the evaporating silicon carbide tends to disproportionate, owing to the differing melting points of silicon and carbon. This can lead to compositional variations in the deposited material. These compositional variations have a significant effect on the electronic properties of the resultant material, and the yield of usable semiconductor grade silicon carbide produced by this method is relatively low.

In an attempt to overcome problems of the PVT process, the prior art has implemented various chemical vapor deposition (CVD) processes. In a typical process of this type, silicon carbide is generated in a deposition chamber by the chemical reaction of precursor gases, typically silane (SiH₄) and a hydrocarbon gas such as propane (C₃H₈). These gases are typically mixed with a carrier gas and fed into a high-temperature furnace which decomposes the gases and allows the silicon and carbon components to react to form silicon carbide. The silicon carbide deposits on a substrate seeded with a silicon carbide crystal. CVD processes can produce a good quality SiC material; however, the process itself is somewhat difficult to control and is relatively inefficient and expensive. The reaction products of the process tend to deposit throughout the entirety of the deposition chamber which results in a significant waste of material and also necessitates frequent cleaning of the deposition apparatus. Also, SiH₄ is relatively expensive and difficult to handle.

As will be explained hereinbelow, the present invention provides a method and apparatus for preparing high purity specialized materials, such as wide band gap semiconductors. The process utilizes low cost, easy to handle starting materials. It is easy to implement and control; and makes efficient use of the starting materials. These and other advantages of this invention will be apparent from the drawings and description which follow.

### BRIEF DESCRIPTION OF THE INVENTION

Disclosed herein is a halide chemical vapor deposition process for depositing a chemical compound which is comprised of at least two different elements. The process employs a first process gas which includes a halogenated compound of a first one of the at least two different elements, and a second process gas which includes hydrogen and a second one of the at least two different elements. A deposition chamber having a deposition substrate supported therein is provided, and the first and second process gases are contacted in the chamber proximate the substrate. In the process of the present invention, the hydrogen in the second process gas reacts with, and decomposes, the halogenated compound in the first process gas, and the first one of the at least two elements reacts with the second one of the at least two element so as to form the chemical compound which deposits on the substrate. In particular instances, at least one of the process gases is preheated to a temperature which is less than the temperature at which the halogenated compound thermally decomposes. In other embodiments of the present invention, the deposition chamber is maintained at a temperature which is less than the temperature at which the halogenated compound thermally decomposes. In certain embodiments of the present invention, the deposition chamber and process gases are maintained at a pressure which is below atmospheric pressure, and in specific instances, this pressure is approximately 200 torr.

In a specific embodiment of the invention, the first process gas includes a silicon-chlorine compound, and the second process gas includes a hydrocarbon material, and the process is operative to produce a deposit of silicon carbide.

Also disclosed is an apparatus for carrying out the invention. The apparatus includes a deposition chamber which is capable of sustaining a pressure less than atmospheric, a substrate support member disposed in the chamber, a first process gas conduit operable to introduce a first process gas from a first process gas supply into the deposition chamber, and a second process gas conduit operable to introduce a second process gas from a source of a second process gas into the deposition chamber. The first and second process gas conduits are configured and disposed so that the process gases do not mix prior to exiting the conduits. In specific embodiments, the apparatus may further include a heater for heating at least one of the process gases while they are in their respective conduits.

### BRIEF DESCRIPTION OF THE DRAWINGS

FIG. 1 is a cross-sectional view of the deposition zone of an apparatus used in the practice of the present invention; and

FIG. 2 is a cross-sectional view of a deposition apparatus structured in accord with the principles of the present invention, incorporating the deposition zone of FIG. 1.

### DETAILED DESCRIPTION OF THE PRESENT INVENTION

The present invention is directed to a halide chemical vapor deposition process particularly well suited for the preparation of highly ordered, very high-purity semiconductors and non-oxide ceramic materials. The method of the present invention utilizes a first process gas which includes a halogenated compound of one of the elements comprising the species to be deposited. This first process gas is reacted with a second process gas, which includes hydrogen as well as a second one of the elements comprising the species being deposited. The two gases are separately conveyed into a deposition chamber and allowed to react only when they are in proximity of a substrate. The gases may be preheated prior to contacting one another.

The use of a halogenated precursor material in the process gas confers significant advantages in the deposition process. Halogenated compounds such as SiCl₄, in the case of deposition of a silicon-based material, are chemically quite stable and therefore simple to utilize. In addition, such materials have very good thermal stability, and can be preheated to relatively high temperatures without undergoing thermal decomposition or other unwanted chemical reactions. By separately preheating one or more of the two process gases, rapid and thorough chemical reaction between the gases is assured once they are contacted. This produces a high-purity deposit, and reaction conditions and system geometry can be readily controlled so that the deposition occurs primarily at the desired substrate.

In a typical deposition process, the first process gas will comprise a halogenated species of at least one of the components being prepared. The halogenated species may be fully halogenated, or may be only partially halogenated. For example, in the case of silicon-based deposits, the first process gas may comprise SiCl₄ as noted above, or it may comprise a partially halogenated species such as SiHCl₃ and the like. In some instances, the process gas may include a halogenated polysilicon species such as Si₂Cl₆ or the like. In other instances, the halogenated species may be a fluorinated species, a brominated species or an iodinated species. In many instances, the process gas will further include a diluent such as argon.

The second process gas will include hydrogen as well as a second component of the material being deposited. The hydrogen may be present as elemental hydrogen (H₂) and/or it may be present in combination with the second component of the material. For example, in the aforementioned deposition of SiC, the second process gas will include a hydrocarbon gas such as propane (C₃H₈), and may further include H₂. The hydrogen in the second process gas reacts with the halogen in the first process gas thereby furthering the reaction which will create the material to be deposited. The second gas may also include a diluent, such as argon.

It will be appreciated that by the use of the method of the present invention, a variety of materials may be prepared. For example, silicon nitride deposits may be prepared by employing a first process gas which includes a silicon halide compound and a second process gas which includes nitrogen and hydrogen, as for example in the form of ammonia. In a similar manner, nitrides of elements such as boron, aluminum and the like may be prepared. Also, in a similar manner, phosphides, arsenides, antimonides and the like may be prepared. While the foregoing discussion was primarily directed to binary compounds, the method of the present invention may be used to prepare materials comprising three or more elements. In such instance, three separate reactive species may be employed; two of the species may be halogenated and one hydrogenated, or one may be halogenated and two hydrogenated. All three gases may be individually directed into the deposition chamber, or two of the species, namely the two halogenated or two hydrogenated species, may be premixed and subsequently reacted with the third. Alternatively, a ternary compound may be prepared from two process gases if one of the gases includes two elements. In yet other embodiments of this invention, dopant or modifying elements may be included in one or more of the process gases.

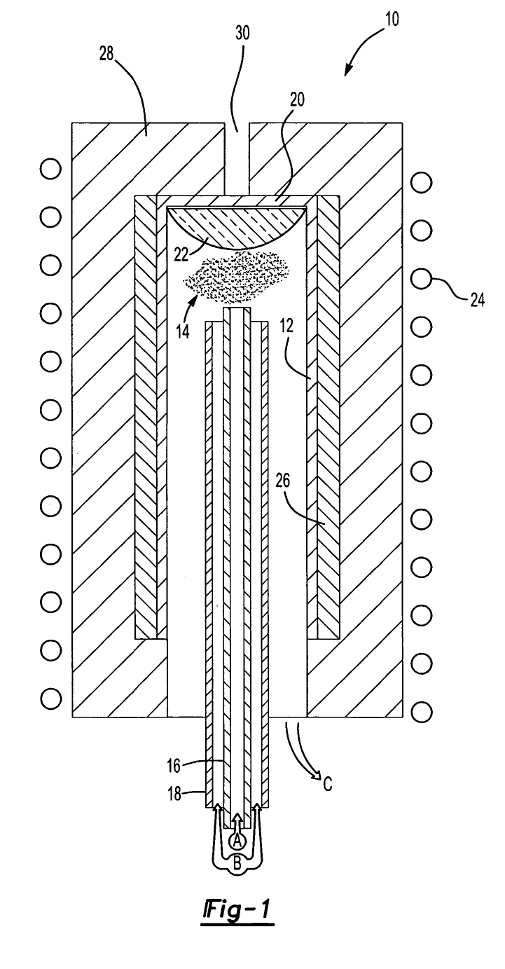

The present invention may be implemented utilizing variously configured deposition apparatus, and may be operative to prepare a variety of materials. For purposes of this disclosure, the application will be described with reference to a particular process for the preparation of high purity silicon carbide material having a 6H (hexagonal) structure. Referring now to FIG. 1, there is shown an apparatus 10, which is a portion of a system which may be utilized for the practice of the present invention. The apparatus of FIG. 1 is referred to as the “hot zone” or “deposition zone” of the system, and is that portion of the system in which the chemical reactions and deposition take place.

The apparatus 10 includes a deposition vessel or chamber 12 which serves to contain the process gases and which defines a reaction zone 14 therein. A first process gas conduit 16 and a second process gas conduit 18 are in fluid communication with respective process gas supplies (not shown) and are operative to deliver their respective process gases to the reaction zone and to prevent mixing of those gases prior to their entry into the reaction zone 14. As illustrated, the conduits 16 and 18 are disposed in a coaxial relationship; however, other configurations may be employed.

The deposition chamber 12 is further configured to include a substrate holder, which in this instance has a seed crystal 20 supported thereupon. In the illustrated process, a body of silicon carbide is being prepared, and the seed crystal is a crystal of hexagonal silicon carbide.

In the operation of the apparatus of FIG. 1 in connection with the preparation of the body of silicon carbide, a first process gas comprising silicon tetrachloride is flowed into the chamber 12 through the first conduit 16 as indicated by arrow A. This gas stream will typically include a diluent gas, such as argon, and may be generated by bubbling a flow or argon through a volume of silicon tetrachloride. A flow of a second process gas is indicated by arrow B and in the preparation of silicon carbide, this gas will preferably comprise a hydrocarbon gas, such as propane, and will typically include additional hydrogen therein. Also, this second process gas may include a diluent, such as argon. The two process gas mixtures encounter one another in the reaction zone 14, and react to produce silicon carbide, which deposits on the seed crystal 20 so as to form silicon carbide boule 22, as well as hydrogen-chloride, which is exhausted from the chamber 12 as indicated by arrow C. The general formula for the reaction is as follows:
3 SiCl₄+C₃H₈+H₂→3 SiC+12 HCl

In a typical deposition process, the reaction zone 14, as well as the substrate, are maintained at an elevated temperature, and one, and generally both, of the process gases are also heated to an elevated temperature prior to contact. The present invention is preferably operated so that the gases are heated to a temperature which is less than a thermal decomposition temperature of the process gases. In the system described above, temperatures are typically maintained at a level of no more than 2300° C. Various methods may be employed for heating the apparatus and gases. As illustrated in FIG. 1, the apparatus is heated by inductive heating. In that regard, a coil 24 carries a high frequency current, such as a 10 kHz current, and is disposed so as to heat an electrically conductive susceptor member 26, which is typically fabricated from graphite. In the illustrated embodiment, the conduits 16 and 18 are also fabricated from graphite and are heated by the coil 24 so as to preheat the gases. The apparatus further includes a body of insulation 28, which in this particular embodiment is a body of carbon foam; although it is to be understood that other types of insulation may be employed. As illustrated, a portion of the insulation 28 is cut away so as to leave an opening 30 which allows access to the surface of the chamber 12 so that its temperature may be measured as, for example, with an optical pyrometer.

Typically, the deposition process is carried out at a pressure below atmospheric, and in that regard, the deposition section of the apparatus of FIG. 1 is enclosed within a vacuum chamber provided with appropriate connections for a vacuum pump, gas inlets, and the like.

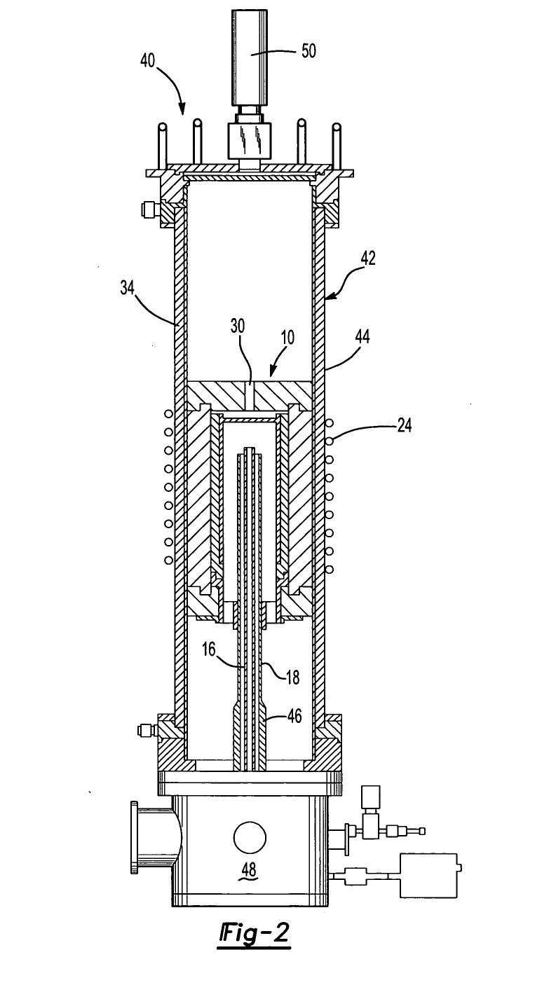

Referring now to FIG. 2, there is shown one specific embodiment of deposition system, comprising a reactor 40, which incorporates and retains the hot zone reaction station of FIG. 1. Reactor 40 of FIG. 2 includes a vacuum chamber 42 having a double-walled cooling jacket 34 fabricated from quartz. The hot zone reactor portion 10 of FIG. 1 is disposed and supported in the reactor 40 by support rod 46 operating in conjunction with the gas conduits 16, 18. In this embodiment, the induction coil 24 is disposed outside of the water jacket 44; although, in other instances, the coil may be disposed within the vacuum chamber 42.

As illustrated, the vacuum chamber 42 is in communication with a base 48 which provides for connection to a process gas supply and a vacuum pump, not shown. As further illustrated in FIG. 2, an optical pyrometer, such as a two-color pyrometer 50, is mounted onto the vacuum chamber 42 so as to allow for measurement of the temperature of the substrate through the opening 30 as noted in FIG. 1.

Operating parameters for the system will depend upon particular system configurations, the material being prepared, and the particular reactants employed. In general, it has been found that in connection with the preparation of silicon carbide materials, as detailed above, the growth rate of the deposit is generally proportional to the pressure of the reactant gases over a range of 20-200 torr, after which the deposition rate generally levels off. Growth rate is also proportional to the flow rate of the process gases, and it has been found that in the deposition of silicon carbide, the growth rate generally increases with increasing temperature of the reaction gas and deposition chamber up to a temperature of approximately 2000° C. Thereafter, the deposition rate begins to decline. While not wishing to be bound by speculation, Applicants assume that this decline is due to an increase in the rate at which deposited material is etched away by reactant species, such as hydrogen. It has further been found that this etching can be suppressed by use of an inert diluent gas, such as argon, in the process gas mixture. In general, some degree of etching may be desirable, since etching and re-deposition serves to remove undesirable species and/or morphologies from the deposited material.

In one typical process, utilizing reactants and apparatus as described above, it has been found that a nine turn induction coil operating at 10 kHz at a current of up to 1200 A, and a power of 20 kw, utilizing a process gas pressure of approximately 200 torr, maintains a temperature of approximately 2100° C. in the chamber, and this produces a growth rate for the silicon carbide deposition of approximately 100-150 microns per hour.

Material thus produced is found to have a very uniform hexagonal morphology over the entire deposited body, which allows for maximum utilization of the thus produced boule. Typical materials have very high purity. Their boron and nitrogen contents are very low, as are the contents of trace metals, such as aluminum, titanium, vanadium and iron. No significant deposits of elemental silicon or carbon were noted in such materials. Materials produced in the use of the present invention have a very low internal strain, and this is resultant from the fact that their structure is highly hexagonal (6H), and as such, have a zero or negligible contents of the 3C morphology as determined by X-ray refraction.

The high degree of control of the process of the present invention allows for very selective control of the composition and/or morphology of the depositing material. Thus, the method and apparatus of the present invention may be utilized to prepare very specialized materials having precisely controlled properties. While the invention has been described with reference primarily to the preparation of binary compounds of silicon and carbon, other compositions, including compounds of three or more elements, may be readily prepared through the use of the present invention. In view of the teachings presented herein, other such embodiments will be apparent to one of skill in the art. Therefore, it should be understood that the foregoing drawings, discussion and description are illustratively of specific embodiments of the invention; but they are not meant to be limitations upon the practice thereof. It is the following claims, including all equivalents, which define the scope of the invention.

1. A halide chemical vapor deposition process for depositing a chemical compound comprised of at least two different elements, said method comprising the steps of:
providing a first process gas which includes a halogenated compound of a first one of said at least two different elements;
providing a second process gas which includes hydrogen and a second one of said at least two different elements;
providing a deposition chamber having a substrate supported therein; and
contacting said first process gas with said second process gas in said chamber, proximate said substrate;
whereby the hydrogen in said second process gas reacts with and decomposes said halogenated compound in said first process gas, and wherein the first one of said at least two elements reacts with the second one of said at least two elements so as to form said chemical compound comprised of said at least two different elements, which chemical compound deposits on said substrate.

2. The method of claim 1, including the further step of preheating at least one of said first process gas and said second process gas to a temperature which is less than a temperature at which said halogenated compound thermally decomposes.

3. The method of claim 1, including the further step of heating said deposition chamber to a temperature which is less than a temperature at which said halogenated compound thermally decomposes.

4. The method of claim 1, including the further step of maintaining said first and second process gases at a pressure which is less than atmospheric.

5. The method of claim 1, wherein in said second process gas, said second element is present as a component of a hydrogen containing molecule.

6. The method of claim 1, wherein said second process gas includes H₂ therein.

7. The method of claim 1, wherein said halogenated compound is a chlorinated compound.

8. The method of claim 1, wherein the chemical compound being deposited is silicon carbide, and said first process gas includes a silicon-halogen compound.

9. The method of claim 8, wherein said second process gas includes a hydrocarbon gas.

10. The method of claim 1, wherein at least one of said first and said second process gases further includes an inert diluent.

11. The method of claim 10, wherein said diluent comprises argon.

12. The method of claim 8, including the further step of preheating said first process gas to a temperature which is no more than 2500° C.

13. The method of claim 12, wherein said step of heating is carried out by inductive heating.

14. The method of claim 8, including the further step of maintaining said first and second process gases at a pressure of approximately 200 torr.

15. The method of claim 1, wherein the first one of said at least two different elements is a Group III element and the second one of said at least two different elements is a Group V element.

16. An apparatus for carrying out a halide chemical vapor deposition process, said apparatus comprising:
a deposition chamber capable of sustaining a pressure less than atmospheric;
a substrate support member disposed in said chamber;
a first process gas conduit operable to introduce a first process gas from a first process gas supply into said deposition chamber;
a second process gas conduit operable to introduce a second process gas, from a source of a second process gas, into said deposition chamber, said first and second process gas conduits being configured and disposed so that said first and second process gases do not mix prior to exiting said conduits; and
a heater for heating at least one of said first and second process gases while they are in their respective conduits.

17. The apparatus of claim 16, wherein said heater is an inductive heater.

18. The apparatus of claim 16, wherein said first and second conduits are disposed in a coaxial relationship.
